(19) United States
(12) Patent Application Publication
(10) Pub. No.: US 2026/0282334 A1
(43) Pub. Date: Sep. 17, 2026

(54) SEMICONDUCTOR MEMORY STRUCTURE AND METHOD FOR FORMING THE SAME

(71) Applicant: Winbond Electronics Corp., Taichung City (TW)

(72) Inventor: Pin-Hung CHEN, Tainan City (TW)

(21) Appl. No.: 19/538,181

(22) Filed: Feb. 12, 2026

(30) Foreign Application Priority Data
Mar. 17, 2025 (TW) 114109789

(51) Int. Cl. H10B 12/00

(52) U.S. Cl. CPC H10B 12/482; H10B 12/02; H10B 12/34

(57) ABSTRACT

A semiconductor memory structure and a method for forming the same are provided. The semiconductor memory structure includes a substrate, a first word line, a second word line and a bit line structure. The first word line and the second word line are embedded in the substrate. The bit line structure extends from the substrate between the first word line and the second word line to above the substrate. The bit line structure includes a first conductive layer, a titanium silicon nitride layer and a second conductive layer. The titanium silicon nitride layer is located on the first conductive layer. The titanium silicon nitride layer includes a lower portion and an upper portion. The atomic percent of silicon in the lower portion is greater than the atomic percent of silicon in the upper portion. The second conductive layer is located on the titanium silicon nitride layer.

### CROSS REFERENCE TO RELATED APPLICATIONS

This application claims priority of Taiwan patent application No. 114109789, filed on Mar. 17, 2025, the entirety of which is incorporated by reference herein.

### TECHNICAL FIELD

The present disclosure relates to a semiconductor memory structure and a method for forming the same, and, in particular, it relates to a bit line structure of a semiconductor memory structure and a method for forming the same.

### BACKGROUND

The current focus of semiconductor manufacturing technology continues to be directed towards the continued miniaturization of component sizes. Unfortunately, this gives rise to many challenges in the effort to increase the density of components in the dynamic random access memory (DRAM) and to improve their overall performance. For example, when the channel length of a transistor continues to shrink as the process evolves, the reliability of the bit lines demands further improvements to improve the yield of components.

### BRIEF SUMMARY

An embodiment of the present disclosure provides a semiconductor memory structure. The semiconductor memory structure includes a substrate, a first word line, a second word line and a bit line structure. The first word line and the second word line are embedded in the substrate. The bit line structure extends from the substrate between the first word line and the second word line to above the substrate. The bit line structure includes a first conductive layer, a titanium silicon nitride layer and a second conductive layer. The titanium silicon nitride layer is located on the first conductive layer. The titanium silicon nitride layer includes a lower portion and an upper portion. The atomic percent of silicon in the lower portion is greater than the atomic percent of silicon in the upper portion. The second conductive layer is located on the titanium silicon nitride layer.

An embodiment of the present disclosure provides a method for forming a semiconductor memory structure. The method includes providing a substrate. The method further includes forming a first word line and a second word line embedded in the substrate. The method further includes forming a bit line structure extending from the substrate between the first word line and the second word line to above the substrate. The bit line structure includes a first conductive layer, a titanium silicon nitride layer, and a second conductive layer. The titanium silicon nitride layer is located on the first conductive layer. The second conductive layer is located on the titanium silicon layer. The titanium silicon nitride layer includes a lower portion and an upper portion. The atomic percent of silicon in the lower portion is greater than the atomic weight percentage of the upper portion. The second conductive layer is located on the titanium silicon nitride layer.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor memory structure in accordance with some embodiments of the disclosure;

FIG. 2 is a flow chart of a method for forming a titanium silicon nitride layer of a bit line of a semiconductor memory structure in accordance with some embodiments of the disclosure; and

FIGS. 3A, 3B, 3C, 3D, 3E, 3F, 3G, and 3H are schematic cross-sectional views of intermediate stages of forming the semiconductor memory structure shown in FIG. 1 in accordance with some embodiments of the disclosure.

### DETAILED DESCRIPTION

The following description is made for the purpose of illustrating the general principles of the disclosure and should not be taken in a limiting sense. The scope of the disclosure is best determined by reference to the appended claims.

In the bit line process of the conventional dynamic random access memory (DRAM), a silicide process is required to reduce the contact resistance between the bit line and the substrate. However, in the silicide process, the high temperature (about 800° C. to 850° C.) annealing process may cause uneven silicide reaction. Some metal material atoms or metal atoms of the metal silicide in the conductive layer of the bit line that react more violently may diffuse downward to the bit line contact, causing the bit line to have an uneven film profile, resulting in failure problems such as leakage. Therefore, a bit line structure of a dynamic random access memory and a method for forming the same are needed to improve the aforementioned problems.

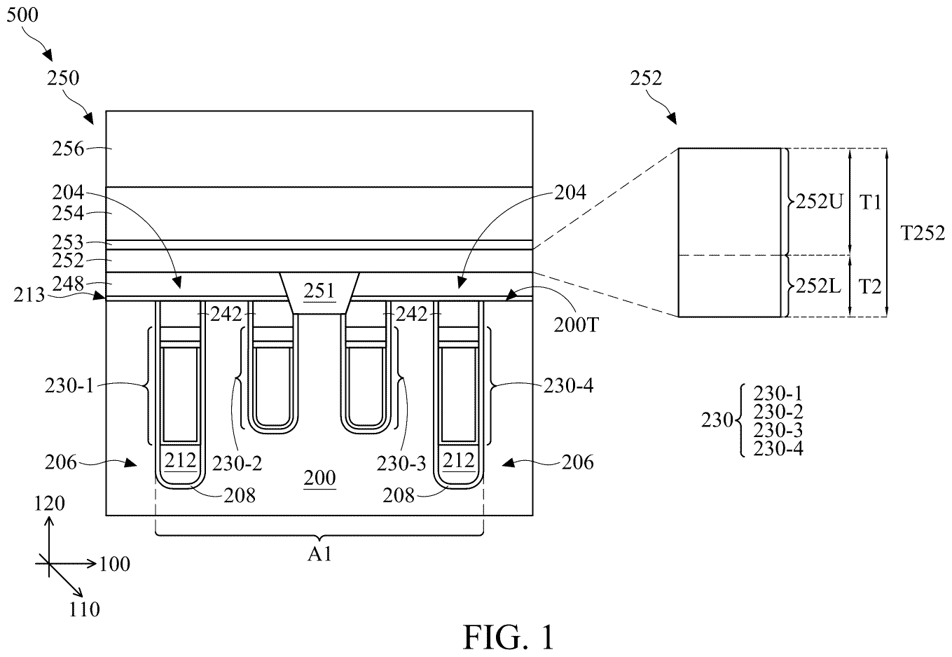

FIG. 1 is a cross-sectional schematic diagram of a semiconductor memory structure 500 in accordance with some embodiments of the disclosure. In some embodiments, the semiconductor memory structure 500 is an integrated circuit structure including a memory array and peripheral components. The memory array includes a dynamic random access memory (DRAM) array or other suitable memory arrays. The peripheral components include metal oxide semiconductor field effect transistors (MOS FETs) or other suitable peripheral components. The semiconductor memory structure 500 includes a substrate 200, an isolation feature 206, an active region A1, a word line 230, and a bit line structure 250. For illustration of the reference directions in the subsequent figures, directions 100 and 110 are substantially parallel to the top surface 200T of the substrate 200, and direction 120 is substantially perpendicular to the top surface 200T of the substrate 200. In addition, direction 100 is a bit line extension direction, and direction 110 is a gate extension direction (or word line extension direction).

In some embodiments, the substrate 200 may include an elemental semiconductor substrate, such as a silicon substrate or a germanium substrate; or a compound semiconductor substrate, such as a silicon carbide substrate, a gallium arsenide substrate. In some embodiments, the semiconductor substrate 200 may be a semiconductor-on-insulator (SOI) substrate. In some embodiments, the conductivity type of the substrate 200 may be P-type or N-type according to design requirements.

A plurality of isolation features 206 are disposed in a plurality of corresponding trenches 204 of the substrate 200. The isolation features 206 may define an active region A1. In some embodiments, the isolation features 206 may be shallow trench isolations (STIs). The isolation features 206 may at least include an insulating liner 208 and an insulating filling layer 212.

The insulating liner 208 of the isolation feature 206 covers the bottom surface and opposite sidewalls of the trench 204. In some embodiments, the insulating liner 208 may be made of silicon oxide, which may be formed using in-situ steam generation (ISSG), chemical vapor deposition (CVD), and/or atomic layer deposition (ALD).

The insulating filling layer 212 fills the trench 204 and covers the insulating liner 208. In some embodiments, the insulating filling layer 212 is formed of a dielectric material, such as silicon oxide (SiO₂), silicon nitride (Si₃N₄), silicon oxynitride (SiON), other suitable materials, and/or a combination thereof. The insulating filling layer 212 may be formed using CVD and/or ALD.

The semiconductor memory structure 500 may include one or more memory cells. The memory cell may include a word line 230 (including word lines 230-1, 230-2, 230-3, and 230-4), a bit line structure 250, and a storage capacitor (not shown). The word line 230 is embedded in a word line trench (not shown) of the substrate 200 in the active region A1, and extends across the active region A1 and the isolation feature 206 along a direction 110. In some embodiments, the word line 230 includes a gate dielectric layer, a conductive structure disposed on the gate dielectric layer, and a work function adjustment structure disposed on the conductive structure. The word line 230 also includes a liner disposed between the conductive structure and the work function adjustment structure.

The memory cell further includes an insulating capping layer 242 and an insulating capping layer 213. The insulating capping layer 242 is disposed on the word line 230 and fills the upper portion of the word line trench. The insulating capping layer 213 is formed on the top surface 200T of the substrate 200 and covers the word line 230. In some embodiments, the insulating capping layer 242 may be formed of a dielectric material, such as silicon nitride or silicon oxide.

The bit line structure 250 of the memory cell is disposed in the substrate 200 between the word line 230-2 and the word line 230-3 and extends onto the substrate 200. In addition, the bit line structure 250 extends along the direction 100 and across the active region A1, the isolation feature 206, the word lines 230-1, 230-2, 230-3, and 230-4.

In some embodiments, the bit line structure 250 includes a conductive layer 248, a first conductive layer 251, a titanium silicon nitride layer 252, a second conductive layer 254, and a mask layer 256 formed sequentially from bottom to top.

The conductive layer 248 is located on the substrate 200 and covers the insulating capping layer 213, the insulating capping layer 242 and the word line 230.

The first conductive layer 251 passes through the insulating capping layer 213 and the conductive layer 248 and extends into a portion of the substrate 200 between the word lines 230-2 and 230-3 to serve as a contact portion of the bit line structure 250. In some embodiments, the conductive layer 248 and the first conductive layer 251 may include the same or similar materials, such as doped or undoped polysilicon.

The titanium silicon nitride layer 252 is located on the first conductive layer 251. The titanium silicon nitride layer 252 includes a lower portion 252L and an upper portion 252U. The lower portion 252L of the titanium silicon nitride layer 252 is connected to the first conductive layer 251. The upper portion 252U is located on the lower portion 252L and connected to the lower portion 252L. The titanium silicon nitride layer 252 is a single-layer structure. For example, the lower portion 252L and the upper portion 252U of the titanium silicon nitride layer 252 are continuously formed without an interface between them.

In some embodiments, the lower portion 252L and the upper portion 252U of the titanium silicon nitride layer 252 may have different atomic percent (at. %) of titanium (Ti), silicon (Si), and nitrogen (N) to have the properties of both metal silicides and barrier materials. For example, the lower portion 252L and the upper portion 252U of the titanium silicon nitride layer 252 may have different atomic percent of silicon. In some embodiments, the atomic percent of silicon in the lower portion 252L of the titanium silicon nitride layer 252 is greater than the atomic percent of silicon in the upper portion 252U. For example, the atomic percent of silicon decrease gradually from the lower portion to the upper portion of the titanium silicon nitride single layer. Therefore, the lower portion 252L of the titanium silicon nitride layer 252 has the properties similar to metal silicide (titanium silicide), which can reduce the junction resistance between the lower portion 252L and the first conductive layer 251, thereby further reducing the resistance of the bit line structure 250 in order to improve the electrical performances of the semiconductor memory structure 500. In addition, the upper portion 252U of the titanium silicon nitride layer 252 has the properties similar to the diffusion barrier layer (titanium nitride). In other words, the diffusion between the upper and lower layers (titanium silicon nitride layer 252 and the overlying second conductive layer 254) can be avoided to enhance the thermal stability and reliability of the semiconductor memory structure 500.

In some embodiments, the atomic percent of silicon in the lower portion 252L of the titanium silicon nitride layer 252 may be between 35% and 45%. If the atomic percent of silicon in the lower portion 252L is too low, the atomic percent of titanium and silicon will increase, which will increase the resistance of the bit line structure 250 and affect the electrical performances of the semiconductor memory structure 500.

In some embodiments, the atomic percent of silicon in the upper portion 252U of the titanium silicon nitride layer 252 may be less than 5%, for example, between 3% and 5%. If the atomic percent of silicon in the upper portion 252U is too high, the atomic percent of titanium and silicon will become lower, which will deteriorate the properties of the diffusion barrier of the upper portion 252U and fail to prevent the conductive atoms (such as metal atoms) of the second conductive layer 254 from penetrating the titanium silicon nitride layer 252 and diffusing into the first conductive layer 251, causing electrical failure of the semiconductor memory structure 500.

In some embodiments, the ratio of the atomic percent of titanium to the atomic percent of silicon in the lower portion 252L of the titanium silicon nitride layer 252 is less than 1.2, for example, between 0.8 and 1.2, or equal to 1 (i.e., the atomic percent of titanium and silicon in the lower portion 252L are the same). If the atomic percent of titanium and silicon are too high, the properties of the metal silicide becomes worse thereby affecting the resistance of the bit line structure 250. In some embodiments, the atomic percent of titanium in the lower portion 252L of the titanium silicon nitride layer 252 is between 35% and 45%. In some embodiments, the atomic percent of nitrogen in the lower portion 252L of the titanium silicon nitride layer 252 is between 10% and 30%.

The ratio of the atomic percent of titanium to the atomic percent of nitrogen in the upper portion 252U of the titanium silicon nitride layer 252 is between 1.8 and 5.3. If the atomic percent of titanium and nitrogen are too low, the properties of the diffusion barrier become worse, thereby affecting the reliability of the semiconductor memory structure 500. In some embodiments, the atomic percent of titanium in the upper portion 252U of the titanium silicon nitride layer 252 is between 60% and 80%. In some embodiments, the atomic percent of nitrogen in the upper portion 252U of the titanium silicon nitride layer 252 is between 15% and 35%.

In some embodiments, the thickness T252 of the titanium silicon nitride layer 252 may be between 13.5 Å and 65 Å. The upper portion 252U of the titanium silicon nitride layer 252 has a first thickness T1, and the lower portion 252L has a second thickness T2. The first thickness T1 is greater than the second thickness T2. For example, the ratio of the first thickness T1 to the second thickness T2 may be between 3:2 and 4:1.

The second conductive layer 254 is located on the upper portion 252U of the titanium silicon nitride layer 252. In some embodiments, the second conductive layer 254 includes a metal material, such as tungsten (W), aluminum (Al), copper (Cu), cobalt (Co), ruthenium (Ru), a metal alloy, or a combination thereof. In some embodiments, a barrier layer 253 such as tungsten silicide (WSi) may be disposed between the second conductive layer 254 and the titanium silicon nitride layer 252.

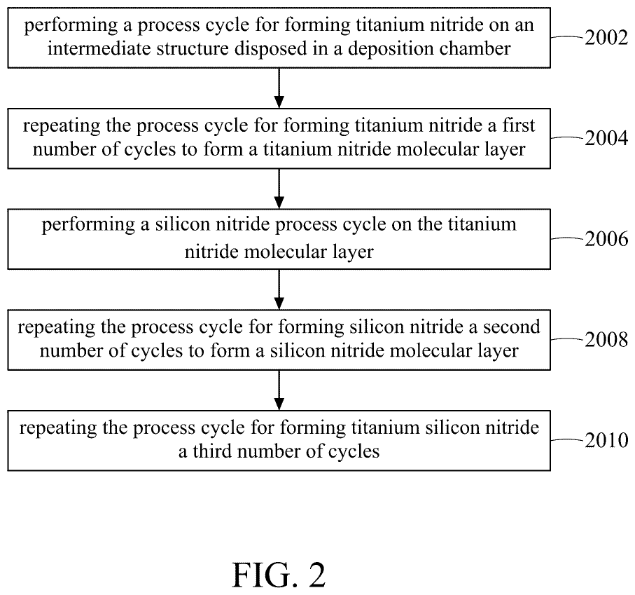

The method for forming the semiconductor structure 500 is described as follow using FIGS. 1 and 2. Referring to FIG. 1, a substrate 200 is provided. Next, a pad layer (not shown) may be formed on the top surface 200T of the substrate 200. The pad layer may be an isolation layer and may serve as a stop layer for subsequent etching process. The pad layer may include silicon oxide (SiO₂), silicon nitride (Si₃N₄), silicon carbonitride (SiCN), silicon oxynitride (SiON), silicon oxycarbonitride (SiOCN), other applicable materials, or a combination thereof.

Next, a patterning process is performed to form a plurality of trenches 204 in the substrate 200 to define the formation positions of the isolation features 206 and the active region A1. In some embodiments, the trenches 204 surround the active region A1.

Next, an insulating liner 208 is conformally formed on the sidewalls and bottom surfaces of the trenches 204. In some embodiments, the insulating liner 208 may include silicon oxide.

Next, a deposition process and a subsequent planarization process are performed to form an insulating filling layer 212 in the trenches 204 of the substrate 200 to form the isolation features 206 and define the active region A1 of the substrate 200.

Next, a patterning process (e.g., photolithography and etching process) is performed to form word line trenches (not shown) in the active region A1 and the isolation feature 206. Since the etching process has different etching rates in the active region A1 and the isolation feature 206, the depths of the trenches formed in the active region A1 and the isolation feature 206 are different. In some embodiments, the trench depth for the word line in the isolation feature 206 is greater than the trench depth for the word line in the active region A1.

Next, multiple deposition processes and etching processes are performed to form word lines 230-1, 230-2, 230-3, 230-4 and an insulating capping layer 242 embedded in the substrate 200 in the word line trenches in the active region A1. The insulating capping layer 242 fills the spaces in the word line trenches above the word lines 230-1, 230-2, 230-3, 230-4.

Next, a deposition process such as atomic layer deposition (ALD) is performed to form an insulating capping layer 213 such as silicon nitride (Si₃N₄), silicon carbonitride (SiCN), silicon oxynitride (SiON), or silicon oxycarbonitride (SiOCN) on the substrate 200 and the isolation feature 206.

Next, a conductive layer 248 is deposited on the insulating capping layer 213, and a hard mask layer (not shown) is deposited on the conductive layer 248. The hard mask layer may include an oxide (e.g., silicon oxide). Next, a patterning process (e.g., lithography and etching processes) is used to form an opening (not shown) on the active region A1 between the word lines 230. In some embodiments, the opening passes through the hard mask layer, the conductive layer 248, the insulating capping layer 213, and the active region A1. In addition, the opening is located between the word lines 230-2 and 230-3. Thereafter, the hard mask layer is removed.

Next, a deposition process and a subsequent planarization process such as chemical mechanical polishing (CMP) are performed to form a first conductive layer 251 in the opening.

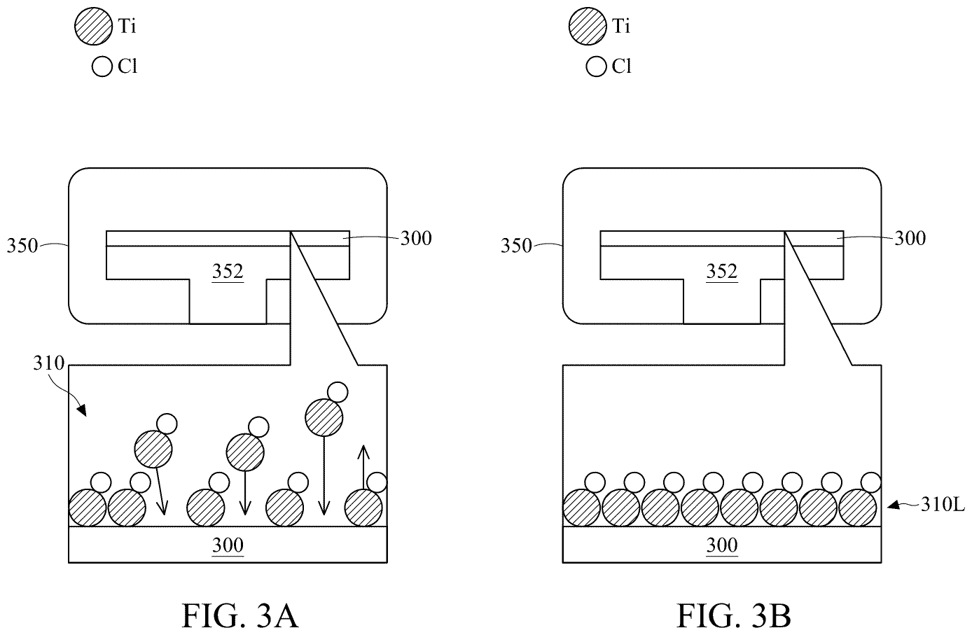

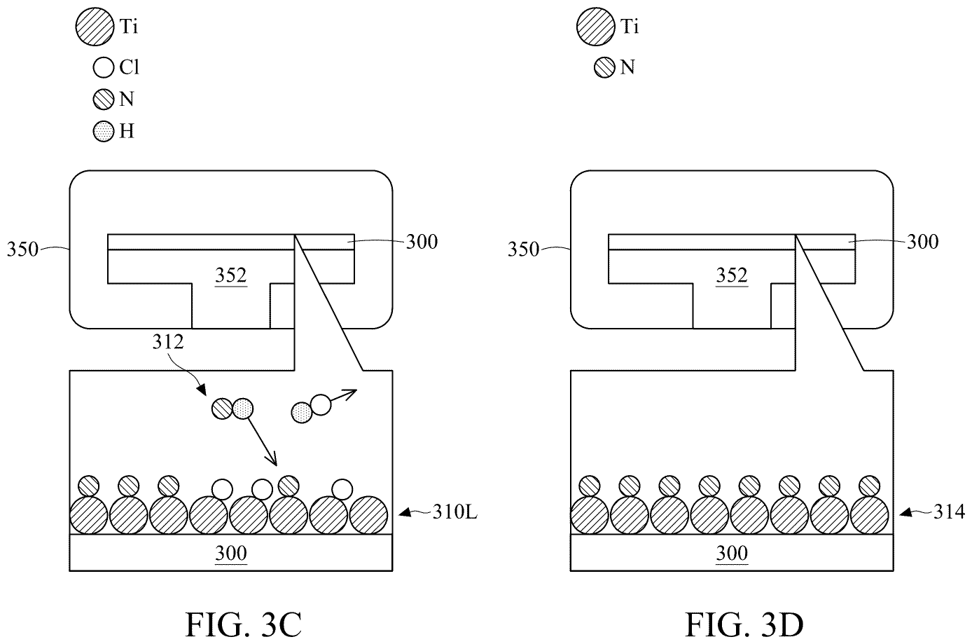

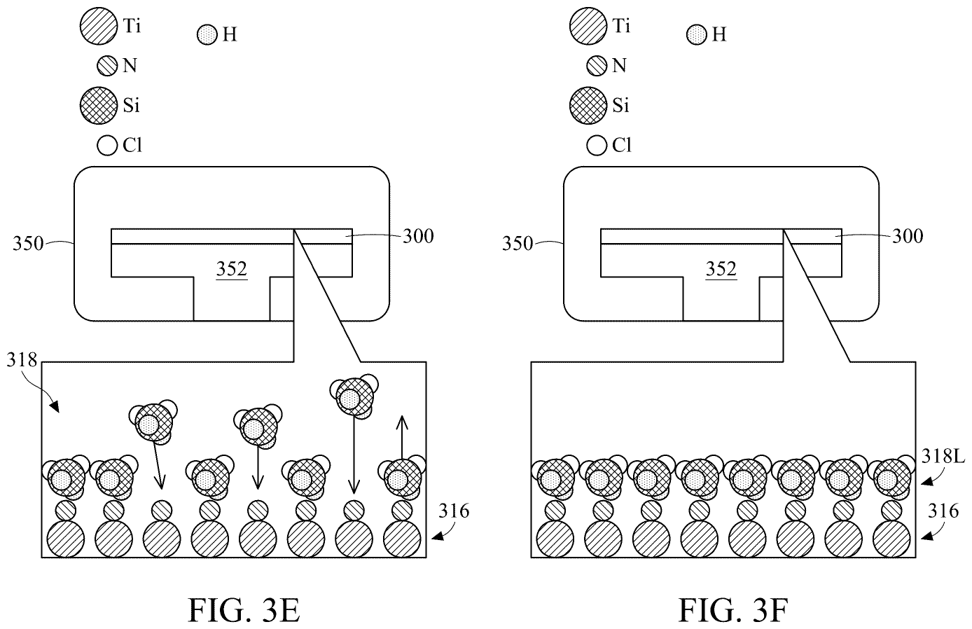

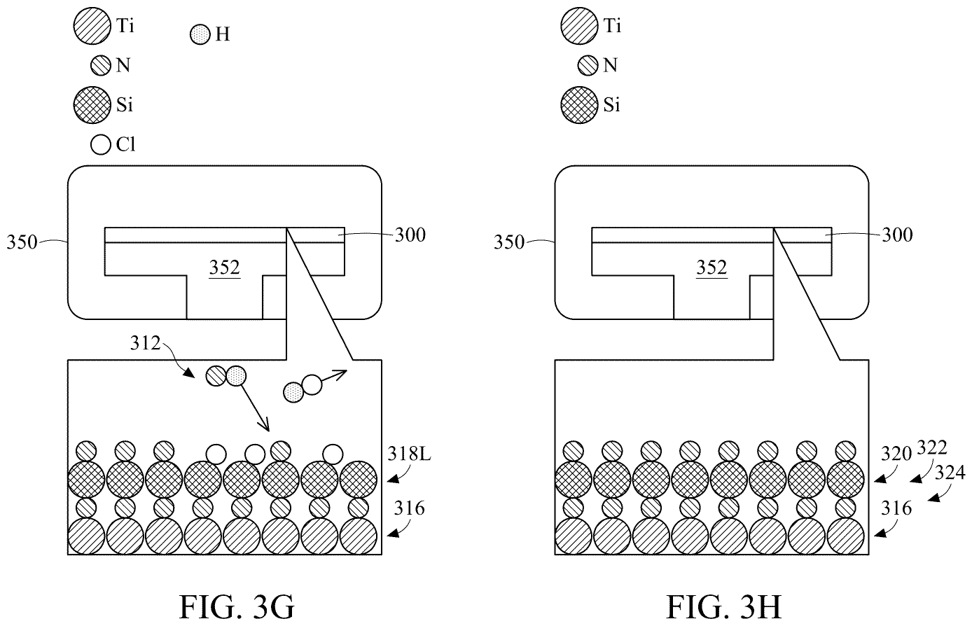

A method for forming the titanium silicon nitride layer 252 (FIG. 1) is described as follow. FIG. 2 is a flow chart of a method for forming the titanium silicon nitride layer 252 of the bit line structure 250 of the semiconductor memory structure 500 in accordance with some embodiments of the disclosure. FIGS. 3A, 3B, 3C, 3D, 3E, 3F, 3G, and 3H are schematic cross-sectional views of the steps of a process cycle for forming titanium nitride and a process cycle for forming silicon nitride in the lower portion 252L or the upper portion 252U (FIG. 1) of the titanium silicon nitride layer 252 in accordance with some embodiments of the disclosure. In some embodiments, the lower portion 252L and the upper portion 252U of the titanium silicon nitride layer 252 may be formed using an atomic layer deposition (ALD) process.

A method for forming the lower portion 252L of the titanium silicon nitride layer 252 is described as follow. First, as shown in FIGS. 2 and 3A, a step 2002 is performed to perform a process cycle for forming titanium nitride on the intermediate structure 300 placed on the platform 352 of the deposition chamber 350. In the embodiment of forming the lower portion 252L of the titanium silicon nitride layer 252, the intermediate structure 300 includes a substrate 200, isolation features 206, a word line 230, and a first conductive layer 251 (FIG. 1). In addition, the process cycle for forming titanium nitride is performed on the first conductive layer 251. As shown in FIG. 3A, the first step of the process cycle for forming titanium nitride is performed to provide a pulse of a first precursor 310 into the deposition chamber 350 and guide it to the intermediate structure 300. Therefore, the exposed surface of the first conductive layer 251 adsorbs the first precursor 310 and forms a first precursor layer 310L (FIG. 3B) for the subsequent reactions. In some embodiments, the first precursor 310 includes a titanium-containing precursor, such as titanium tetrachloride (TiCl₄). In some embodiments in which the first precursor 310 is titanium tetrachloride, titanium atoms of titanium tetrachloride are chemically bonded to the surface of the first conductive layer 251, and chlorine atoms are exposed to the ambient gas of the deposition chamber 350.

As shown in FIG. 3B, the second step of the process cycle for forming titanium nitride is then performed to purge the deposition chamber 350. A purge gas (e.g., an inert gas including argon, xenon, helium, or the like) (not shown) may be delivered into the deposition chamber 350. In addition, an exhaust device (not shown) connected to the deposition chamber 350 may be used to remove the first precursor 310 (FIG. 3A) remaining in the deposition chamber 350.

As shown in FIG. 3C, the third step of the process cycle for forming titanium nitride is then performed to provide a pulse of the second precursor 312 into the deposition chamber 350 and guide it to the intermediate structure 300, so that the first precursor layer 310L reacts with the second precursor 312. After the third step is performed, a titanium nitride monolayer 314 is formed (as shown in FIG. 3D). In some embodiments, the titanium nitride monolayer 314 may be substantially free of silicon. In some embodiments, the second precursor 312 includes ammonia (NH3). In some embodiments in which the first precursor 310 is titanium tetrachloride and the second precursor 312 is ammonia, the titanium tetrachloride layer reacts with the ammonia to form a titanium nitride (TiN) monolayer (FIG. 3D) and hydrogen chloride (HCl) gas, and the hydrogen chloride gas may be pumped out of the deposition chamber 350 by the exhaust device.

As shown in FIG. 3D, the fourth step of the process cycle for forming titanium nitride is then performed to purge the deposition chamber 350. A purge gas (e.g., an inert gas) may be delivered into the deposition chamber 350. In addition, the exhaust device (not shown) connected to the deposition chamber 350 may be used to remove the second precursor 312 and hydrogen chloride (HCl) gas (FIG. 3C) remaining in the deposition chamber 350, and retain the titanium nitride monolayer 314 on the intermediate structure 300. After purging the deposition chamber 350, a process cycle for forming titanium nitride is completed.

Next, a step 2004 is performed to repeat the process cycle for forming titanium nitride a first number of cycles to form a titanium nitride molecular layer 316 (FIG. 3E shows the surface portion of the titanium nitride molecular layer 316) including a plurality of titanium nitride monolayers 314. For example, the first step, the second step, the third step and the fourth step of the process cycle for forming titanium nitride are repeatedly performed to form the titanium nitride molecular layer 316.

Next, ae step 2006 is performed to perform a process cycle for forming silicon nitride on the titanium nitride molecular layer. As shown in FIG. 3E, the first step of the process cycle for forming silicon nitride is performed to provide a pulse of a third precursor 318 into the deposition chamber 350 and guide it to the intermediate structure 300. Therefore, the exposed surface of the titanium nitride molecular layer 316 adsorbs the third precursor 318 and forms a third precursor layer 318L (FIG. 3F) for subsequent reactions. In some embodiments, the third precursor 318 includes a silicon-containing precursor, such as dichlorosilane (SiH2Cl2, DCS). In some embodiments in which the third precursor 318 is dichlorosilane, the silicon atoms of the dichlorosilane are chemically bonded to the surface of the titanium nitride molecular layer 316, and the chlorine atoms are exposed to the ambient gas of the deposition chamber 350.

As shown in FIG. 3F, the second step of the process cycle for forming silicon nitride is then performed to purge the deposition chamber 350. A purge gas (e.g., an inert gas including argon, xenon, helium, or the like) may be delivered into the deposition chamber 350. In addition, an exhaust device (not shown) connected to the deposition chamber 350 may be used to remove the third precursor 318 remaining in the deposition chamber 350.

As shown in FIG. 3G, the third step of the process cycle for forming silicon nitride is then performed to provide a pulse of the second precursor 312 into the deposition chamber 350 and guide it to the intermediate structure 300, so that the third precursor layer 318L reacts with the second precursor 312. After the third step is performed, a silicon nitride monolayer 320 is formed (as shown in FIG. 3H). In some embodiments, the second precursor 312 includes ammonia (NH₃). In some embodiments in which the third precursor 318 is dichlorosilane and the second precursor 312 is ammonia, the dichlorosilane layer reacts with the ammonia to form a silicon nitride (SiN) monolayer and hydrogen chloride (HCl) gas, and the hydrogen chloride gas may be pumped out of the deposition chamber 350 by the exhaust device.

As shown in FIG. 3H, the fourth step of the process cycle for forming silicon nitride is then performed to purge the deposition chamber 350. A purge gas (e.g., an inert gas) may be delivered into the deposition chamber 350. In addition, an exhaust device (not shown) connected to the deposition chamber 350 may be used to remove the second precursor 312 and hydrogen chloride (HCl) gas remaining in the deposition chamber 350, and retain the silicon nitride monolayer 320 on the titanium nitride molecular layer 316. After purging the deposition chamber 350, a process cycle for forming silicon nitride is completed.

Next, a step 2008 is performed to repeat the process cycle for forming titanium nitride a second number of cycles to form a silicon nitride molecular layer 322 including a plurality of silicon nitride monolayers 320 (the silicon nitride molecular layer 322 in FIG. 3H includes one silicon nitride monolayer 320). For example, the first step, the second step, the third step, and the fourth step of the process cycle for forming silicon nitride may be repeated to form the silicon nitride molecular layer 322 in the order of the first step, the second step, the third step, and the fourth step of the process cycle for forming silicon nitride.

During the step 2008, the silicon nitride molecular layer 322 reacts with the underlying titanium nitride molecular layer 316 to form a titanium silicon nitride molecular layer 324. After the titanium silicon nitride molecular layer is formed, a process cycle for forming titanium silicon nitride is completed.

Next, a step 2010 is performed to repeat the process cycle for forming titanium silicon nitride a third number of cycles. After the step 2010 is performed, the lower portion 252L of the titanium silicon nitride layer 252 is formed. In the embodiment of forming the lower portion 252L of the titanium silicon nitride layer 252, the ratio of the first number of cycles to the second number of cycles may be between 2:1 and 3:1. The third number of cycles may be between 5 and 10. In addition, the thickness of the titanium silicon nitride molecular layer 324 may be between 1.5 Å and 2.5 Å.

After forming the lower portion 252L of the titanium silicon nitride layer 252, the steps 2002, 2004, 2006, 2008, 2010 may be performed on the intermediate structure 300 disposed in the deposition chamber 350 in the order of the steps 2002, 2004, 2006, 2008, 2010 to continuously form the upper portion 252U of the titanium silicon nitride layer 252 in the same deposition chamber 350. The ratio of the first number of cycles to the second number of cycles of forming the upper portion 252U is higher than that of forming the lower portion 252L. In the embodiment of forming the upper portion 252U of the titanium silicon nitride layer 252, the ratio of the first number of cycles to the second number of cycles may be between 25:1 and 40:1, and the third number of cycles may be between 1 and 2. The thickness of the titanium silicon nitride molecular layer 324 may be between 6 Å and 20 Å. The third number of cycles of forming the upper portion 252U is lower than that of forming the lower portion 252L. The third number of cycles may be controlled to adjust the ratio of the thickness of the upper portion to the thickness of the lower thickness of the titanium silicon nitride layer. After the upper portion 252U of the titanium silicon nitride layer 252 is formed, the titanium silicon nitride layer 252 is formed.

Next, as shown in FIG. 1, a deposition process is performed to sequentially form a barrier layer 253, a second conductive layer 254, and a mask layer 256 on the titanium silicon nitride layer 252. Afterwards, a patterning process is performed on the first conductive layer 251, the titanium silicon nitride layer 252, the second conductive layer 254, and the mask layer 256 to form a bit line structure 250.

In addition, additional components may be formed on the semiconductor memory structure 500 of FIG. 1. For example, a patterning process, a deposition process, and a subsequent removal process may be performed to form a storage capacitor (not shown) on the active region A1 between different bit line structures 250. After the above processes, the semiconductor memory structure 500 is formed.

In some embodiments, the titanium silicon nitride layer 252 formed by atomic layer deposition at a relatively low process temperature (about 500° C. to 600° C.) has the functions of both metal silicides and barrier materials. Therefore, it is not necessary to perform a conventional metal silicide process, especially a high temperature annealing process in a metal silicide process, to form a metal silicide layer. Compared to the conventional processes, the method for forming the semiconductor memory structure 500 may further prevent the semiconductor memory structure 500 from the bit line leakage failure problem result from the metal atoms of the conductive layer above the metal silicide or the metal atoms of the metal silicide from diffusing into the first conductive layer 251 due to uneven silicide reaction, thereby causing the bit line film layer profile of the semiconductor memory structure 500 to be uneven.

In the method for forming a semiconductor memory structure in accordance with some embodiments of the disclosure, a titanium silicon nitride layer is formed by low-temperature atomic layer deposition. The titanium silicon nitride layer includes a lower portion and an upper portion. The atomic percent of silicon in the lower portion is greater than that in the upper portion, so as the titanium silicon nitride layer may be used to replace the titanium silicide formed by the high-temperature metal silicide process in the conventional technology. The electromigration problem of the upper bit line conductive layer caused by high temperature can be avoided, so as to improve the electrical performances and reliability of the semiconductor memory structure.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor memory structure, comprising:
a substrate;
a first word line and a second word line embedded in the substrate; and
a bit line structure extending from the substrate between the first word line and the second word line to above the substrate, wherein the bit line structure comprises:
a first conductive layer;
a titanium silicon nitride layer located on the first conductive layer, wherein the titanium silicon nitride layer comprises:
a lower portion and an upper portion, wherein the atomic percent of silicon in the lower portion is greater than the atomic percent of silicon in the upper portion; and
a second conductive layer located on the titanium silicon nitride layer.

2. The semiconductor memory structure as claimed in claim 1, wherein the atomic percent of silicon in the lower portion is between 35% and 45%, and the atomic percent of silicon in the upper portion is less than 5%.

3. The semiconductor memory structure as claimed in claim 1, wherein the atomic percent of titanium in the lower portion is between 35% and 45%.

4. The semiconductor memory structure as claimed in claim 1, wherein a ratio of the atomic percent of titanium to the atomic percent of silicon in the lower portion is between 0.8 and 1.2.

5. The semiconductor memory structure as claimed in claim 1, wherein the atomic percent of titanium in the upper portion is between 60% and 80%, and the atomic percent of nitrogen in the upper portion is between 15% and 35%.

6. The semiconductor memory structure as claimed in claim 1, wherein a ratio of the atomic percent of titanium to the atomic percent of nitrogen in the upper portion is between 1.8 and 5.3.

7. The semiconductor memory structure as claimed in claim 1, wherein the upper portion has a first thickness, the lower portion has a second thickness, and the first thickness is greater than the second thickness.

8. The semiconductor memory structure as claimed in claim 7, wherein a ratio of the first thickness to the second thickness is between 3:2 and 4:1.

9. The semiconductor memory structure as claimed in claim 1, wherein the first conductive layer comprises polysilicon and the second conductive layer comprises tungsten, aluminum, copper, or a combination thereof.

10. A method for forming a semiconductor memory structure, comprising:
providing a substrate;
forming a first word line and a second word line embedded in the substrate; and
forming a bit line structure extending from the substrate between the first word line and the second word line to above the substrate, wherein the bit line structure comprises:
a first conductive layer;
a titanium silicon nitride layer located on the first conductive layer, wherein the titanium silicon nitride layer comprises:
a lower portion and an upper portion, wherein the atomic percent of silicon in the lower portion is greater than the atomic percent of silicon in the upper portion; and
a second conductive layer located on the titanium silicon nitride layer.

11. The method for forming a semiconductor memory structure as claimed in claim 10, wherein forming the lower portion or the upper portion of the titanium silicon nitride layer comprises:
performing a process cycle for forming titanium nitride on an intermediate structure disposed in a deposition chamber;
repeating the process cycle for forming titanium nitride a first number of cycles to form a titanium nitride molecular layer;
performing a process cycle for forming silicon nitride on the titanium nitride molecular layer;
repeating the process cycle for forming silicon nitride a second number of cycles to form a silicon nitride molecular layer, so that the silicon nitride molecular layer reacts with the titanium nitride molecular layer to complete a process cycle for forming titanium silicon nitride, wherein the process cycle for forming titanium silicon nitride is used to form a titanium silicon nitride molecular layer; and
repeating the process cycle for forming titanium silicon nitride a third number of cycles.

12. The method for forming a semiconductor memory structure as claimed in claim 11, wherein:
the intermediate structure comprises the substrate with the first word line, the second word line and the first conductive layer, during the formation of the lower portion of the titanium silicon nitride layer, and
the intermediate structure comprises the substrate with the first word line, the second word line, the first conductive layer and the lower portion of the titanium silicon nitride layer, during the formation of the upper portion of the titanium silicon nitride layer.

13. The method for forming a semiconductor memory structure as claimed in claim 11, wherein performing the process cycle for forming titanium nitride comprises:
(a) providing a pulse of a first precursor into the deposition chamber;
(b) purging the deposition chamber after step (a);
(c) providing a pulse of a second precursor into the deposition chamber to form a titanium nitride monolayer after step (b); and
(d) purging the deposition chamber after step (c).

14. The method for forming a semiconductor memory structure as claimed in claim 13, wherein performing the process cycle for forming silicon nitride comprises:
(e) providing a pulse of a third precursor into the deposition chamber after step (d);
(f) purging the deposition chamber after step (e);
(g) providing a pulse of the second precursor into the deposition chamber to form a silicon nitride monolayer after step (f); and
(h) purging the deposition chamber after step (g).

15. The method for forming a semiconductor memory structure as claimed in claim 11, wherein a ratio of the first number of cycles to the second number of cycles of forming the upper portion of the titanium silicon nitride layer is higher than that of forming the lower portion of the titanium silicon nitride layer.

16. The method for forming a semiconductor memory structure as claimed in claim 11, wherein the third number of cycles of forming the upper portion of the titanium silicon nitride layer is lower than that of forming the lower portion of the titanium silicon nitride layer.

17. The method for forming a semiconductor memory structure as claimed in claim 10, wherein a ratio of the atomic percent of titanium to the atomic percent of silicon in the lower portion of the titanium silicon nitride layer is between 0.8 and 1.2.

18. The method for forming a semiconductor memory structure as claimed in claim 11, wherein a ratio of the first number of cycles to the second number of cycles of forming the lower portion of the titanium silicon nitride layer is between 2:1 and 3:1, and a ratio of the first number of cycles to the second number of cycles is between 25:1 and 40:1 for forming the upper portion of the titanium silicon nitride layer.

19. The method for forming a semiconductor memory structure as claimed in claim 11, wherein the third number of cycles is between 5 and 10 for forming the lower portion of the titanium silicon nitride layer, and the third number of cycles is between 1 and 2 for forming the upper portion of the titanium silicon nitride layer.

20. The method for forming a semiconductor memory structure as claimed in claim 10, wherein the ratio of the atomic percent of titanium to the atomic percent of nitrogen in the upper portion of the titanium silicon nitride layer is between 1.8 and 5.3.
